(19) United States
(12) Patent Application Publication
(10) Pub. No.: US 2002/0163001 A1
(43) Pub. Date: Nov. 7, 2002

(54) Surface mount light emitting device package and fabrication method

(76) Inventor: David Mulford Shaddock, Schenectady, NY (US)

Correspondence Address: GENERAL ELECTRIC COMPANY, GLOBAL RESEARCH CENTER, PATENT DOCKET RM. 4A59, PO BOX 8, BLDG. K-1 ROSS, NISKAYUNA, NY, 12309, US

(21) Appl. No.: 09/681,599

(22) Filed: May 4, 2001

(51) Int. Cl. H01L 27/15

(52) U.S. Cl. 257/79

(57) ABSTRACT

A surface mount light emitting device package comprises: a surface mount lead frame comprising a thermally and electrically conductive reflector cup and leads; a light emitting device situated within the reflector cup and coupled to the leads; and encapsulant disposed around the light emitting device and around the reflector cup.

### BACKGROUND OF THE INVENTION

The invention relates generally to packaging for light emitting devices.

Light emitting devices such as semiconductor light emitting diodes are semiconductor chips that are mounted in a package and emit radiation in response to an applied voltage or current. These devices are used in a number of commercial applications such as automotive, display, safety/emergency and directed area lighting. A high brightness is desired for these applications. In the conventional light emitting devices, in order to obtain a higher brightness, the current was increased. However, an increase in current also causes an increase in the operating or junction temperature. This increase in junction temperature undesirably reduces efficiency and operating lifetime.

Conventional techniques for packaging light emitting devices often involve molding a thin and flat-surfaced lead frame in plastic. Packages resulting from such techniques typically have wattages limited to about 150° C. per watt (˜130 milliwatts).

It would therefore be desirable to provide a surface mount light emitting device package with improved optical and thermal performance.

### SUMMARY OF INVENTION

Briefly, in accordance with one embodiment of the present invention, a surface mount light emitting device package comprises: a surface mount lead frame comprising a thermally and electrically conductive reflector cup and leads; a light emitting device situated within the reflector cup and coupled to the leads; and encapsulant disposed around the light emitting device and around the reflector cup.

### BRIEF DESCRIPTION OF DRAWINGS

The features of the invention believed to be novel are set forth with particularity in the appended claims. The invention itself, however, both as to organization and method of operation, together with further objects and advantages thereof, may best be understood by reference to the following description taken in conjunction with the accompanying drawings, where like numerals represent like components, in which:

FIGS. 1 and 2 are sectional side and top views of a surface mount light emitting device package according to one embodiment of the present invention.

FIG. 3 is a sectional side view of a surface mount light emitting device package according to another embodiment of the present invention.

FIGS. 4 and 5 are sectional side and top views of a surface mount light emitting device package according to another embodiment of the present invention.

FIG. 6 is a sectional side view of a surface mount light emitting device package according to another embodiment of the present invention.

### DETAILED DESCRIPTION

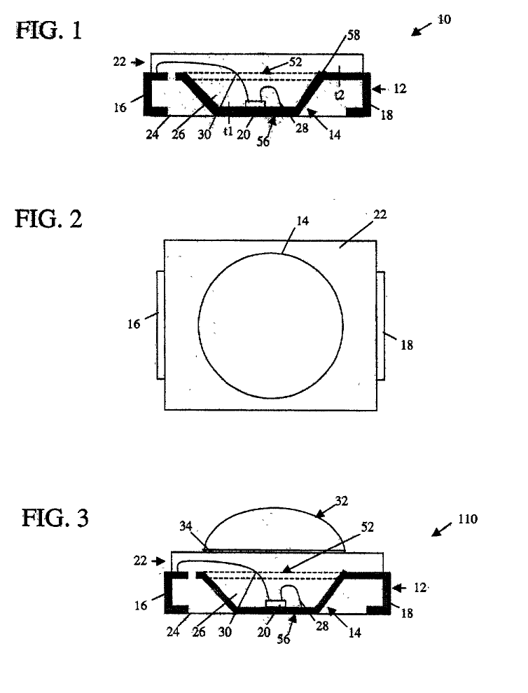

FIGS. 1 and 2 are sectional side and top views of a surface mount light emitting device package 10 comprising a surface mount lead frame 12 comprising a thermally and electrically conductive reflector cup 14 and leads 16 and 18, a light emitting device 20 situated within the reflector cup and coupled to the leads, and encapsulant 22 disposed around the light emitting device and around the reflector cup. In one embodiment, the reflector cup comprises an integral reflector cup such that at least a portion of reflector cup 14 comprises the same piece of material (whether thicker or of substantially the same thickness) as at least one of the leads (shown as lead 18 in FIG. 1). Although FIG. 1 illustrates lead 18 as being coupled to reflector cup 14 for purposes of example, it is not necessary that the reflector cup be coupled to any of the leads.

Lead frame 12 comprises a thermally and electrically conductive material with good thermal conductivity properties such as copper having a thickness ranging from about 0.2 millimeters to about 0.4 millimeters, for example, and in one embodiment lead frame 12 has a thickness of about 0.25 millimeters. If the material of the lead frame does not provide a desired level of reflectivity, optional reflective metallization 58 may be applied to the surface of reflector cup 14. Metallization 58 may comprise a material such as silver or aluminum having a thickness of about 125 micrometers, for example. In another embodiment the lead frame (including the leads) comprises a reflective material such as aluminum, and no additional metallization 58 is used. Light emitting device 20 may comprise any suitable lighting emitting device such as a light emitting diode, for example. The present invention is expected to be particularly advantageous for light emitting devices having wattages in the range of up to about 1 watt, for example. Although not required, light emitting device 20 will typically be attached to reflector cup 14 using a solder or a thermally (and optionally electrically) conductive epoxy.

Light emitting device 20 may be coupled to leads 28 and 30 via any suitable technique. In the embodiment of FIG. 1, for example, wire bonds 28 and 30 are used to create electrical contact between light emitting device 20 and leads 16 and 18. In another embodiment, prior to being situated within the reflector cup, the light emitting device is attached using a flip chip bond to a substrate (not shown) comprising a material such as silicon, a ceramic, or a printed circuit board, for example, which is in turn situated within the reflector cup and coupled to the leads with wire bonds.

Encapsulant 22 may be disposed around the reflector cup and light emitting device either in a single step or multiple step process. Additionally, encapsulant 22 may optionally comprise multiple encapsulants. For example, in one embodiment a first encapsulant 24 is disposed around the reflector cup and a second encapsulant 26 is disposed around the light emitting device. First and second encapsulants 24 and 26 may comprise either the same material or different materials and they may be disposed either simultaneously or sequentially. In one embodiment, it is useful to dispose the second encapsulant after situating the light emitting device within the reflector cup.

If encapsulant 22 comprises a uniform material (that is, the same material surrounds both the reflector cup and the light emitting device), the material may comprise a substantially transparent material. If encapsulant 22 comprises multiple materials, the material around light emitting device 20 comprises a substantially transparent material. Substantially transparent is intended to mean having a transparency of at least 80%, and examples of suitable materials include an epoxy, such as a cycloaliphatic or BPA epoxy, a silicone, or a glass material. Further examples of epoxies are described in Shaddock, “Dual Encapsulation for and LED,” U.S. patent application Ser. No. 09/714,434, filed Nov. 17, 2000, for example. In one embodiment a transfer molding process is used wherein epoxy in a semi-cured state is made to flow into a mold under elevated temperature and pressure conditions.

In one embodiment, as shown in FIG. 1, for example, at least one of the leads 18 is substantially planar to a light emitting surface 52 of the reflector cup and is formed so as to be substantially planar to a non-light emitting surface 56 of the reflector cup . In the embodiment of FIG. 1, lead 18 is shown as being wrapped around and under the encapsulant, whereas, in the embodiment of FIG. 6, lead 216 is shown as wrapped around the encapsulant and flaring outward from the encapsulant. The other of the leads 16 is also typically formed so as to have surfaces substantially planar to both the light emitting and non-light emitting surfaces of the reflector cup. Substantially planar is intended to mean that the surfaces of the leads and the reflector cup are either planar or within no more than about 100 micrometers of being planar. The lead wrapping shaping may occur either before or after the molding of the encapsulant(s).

In the embodiment of FIG. 1, a thickness t1 of integral material of the reflector cup comprises a substantially similar thickness as a thickness t2 of the leads. “Integral material” is mean to include the material of the reflector cup except for any optional metallization 58. “Substantially similar thickness” is meant to include thicknesses in the range of about ninety percent to about one hundred percent of the thickness of the leads. In this embodiment, the reflector cup can be fabricated by stamping a uniform thermally and electrically conductive sheet, for example, to both cause the depression for the reflector cup and cut away windows to provide separation between the reflector cup and at least one lead 16. Stamping may slightly alter the thickness of the integral material of the reflector cup.

FIG. 3 is a sectional side view of a surface mount light emitting device package 110 according to another embodiment of the present invention further including a lens 32. In one embodiment, disposing encapsulant 22 comprises disposing the encapsulant so as to form lens 32. In another embodiment, the lens is provided in a separate process step from the encapsulation disposition. In either embodiment, the encapsulant mechanically and optically couples the lens and the light emitting device.

In a more specific embodiment wherein the lens is applied separately from the encapsulant, the lens comprises a plastic or a glass lens, for example. In another optional embodiment, as shown in FIG. 3, an ultraviolet filter 34 may be situated between the lens and the light emitting device. The ultraviolet filter may comprise a thin film of epoxy or glass, for example. The lens and/or the filter may be attached to the package by an adhesive such as a glue, an epoxy, or a silicone, for example.

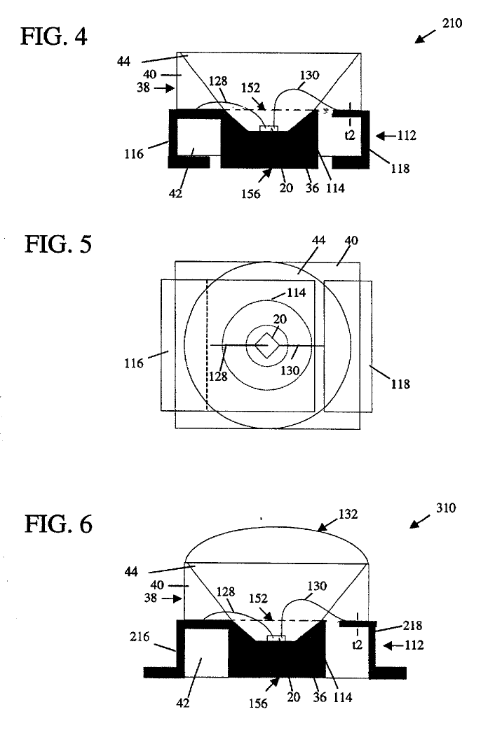

FIGS. 4 and 5 are sectional side and top views of a surface mount light emitting device package 210 according to another embodiment of the present invention wherein a thickness t3 of integral material 36 of the reflector cup is thicker than a thickness t2 of the leads. In one embodiment, integral material 36 comprises copper having a maximum thickness ranging from about 0.9 millimeters to about 1.4 millimeters.

Having the reflector cup material be thicker than leads 116 and 118 improves the thermal performance of the package at the expense of increased fabrication costs. In one embodiment reflector cup portion 36 and leads 116 and 118 are fabricated by rolling the assembly to leave a thicker portion in the middle and thinner portions on the edges, and the reflector cup 114 is formed by stamping.

In the embodiment of FIG. 4, as discussed above with respect to reflector cup 14 in the embodiment of FIG. 1, at least one of the leads is substantially planar to a light emitting surface 152 of the integral material of reflector cup 114 and is formed so as to be substantially planar to a non-light emitting surface 156 of the integral material of the reflector cup.

As discussed with respect to FIGS. 1 and 2, encapsulant 42 may be disposed around the reflector cup and light emitting device either in a single step or a multiple step process. In one embodiment, for example, encapsulant in the regions of 42 and 40 comprises a hard plastic material that may or may not be transparent, and encapsulant in the region 44 comprises a transparent epoxy.

FIG. 6 is a sectional side view of a surface mount light emitting device package 310 according to another embodiment of the present invention. FIG. 6 is similar to the embodiment of FIG. 4 with the addition of lens 132. Lens 132 and/or filter 34 of FIG. 3 may be applied in the embodiment of FIG. 6 using any of the methods described above with respect to FIG. 3.

The thermal conduction path under the light emitting devices combined with the optical reflection and surface mount capability have many advantages, including reduced fabrication costs as compared with conventional techniques combined with potential for use with higher currents for increased light brightness. It is expected that wattages of about 1 watt can be tolerated for the embodiments of the present invention, and that embodiments wherein the integral material of the reflector cup is thicker than the leads will additionally be capable of managing pulsed (transient) power.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A surface mount light emitting device package comprising:
a surface mount lead frame comprising a thermally and electrically conductive reflector cup and leads;
a light emitting device situated within the reflector cup and coupled to the leads; and
encapsulant disposed around the light emitting device and around the reflector cup.

2. The package of claim 1 wherein the encapsulant comprises a uniform material.

3. The package of claim 1 wherein the encapsulant comprises a first encapsulant around the reflector cup and a second encapsulant around the light emitting device.

4. The package of claim 1 wherein the encapsulant forms a lens with respect to the light emitting device.

5. The package of claim 1 further comprising a lens with the encapsulant mechanically and optically coupling the lens and the light emitting device.

6. The package of claim 5 further comprising an ultraviolet filter situated between the lens and the light emitting device.

7. The package of claim 1 wherein the reflector cup comprises an integral reflector cup.

8. The package of claim 7 wherein a thickness (t1) of integral material of the reflector cup comprises a substantially similar thickness as a thickness (t2) of the leads.

9. The package of claim 1 wherein a thickness (t3) of integral material of the reflector cup is thicker than a thickness (t2) of the leads.

10. The package of claim 9 wherein at least one of the leads is substantially planar to a light emitting surface of the integral material of the reflector cup and wraps around the encapsulant to be substantially planar to a non-light emitting surface of the integral material of the reflector cup.

11. The package of claim 1 wherein the surface mount lead frame further comprises a reflective metallization for reflecting light from the light emitting device.

12. A surface mount light emitting device package comprising:
a surface mount lead frame comprising an integral thermally and electrically conductive reflector cup and leads, the reflector cup being electrically coupled to one lead and electrically separated from at least one lead;
a light emitting device situated within the reflector cup and coupled to the leads; and
encapsulant disposed around the light emitting device and around the reflector cup.

13. The package of claim 12 wherein the surface mount lead frame further comprises a reflective metallization for reflecting light from the light emitting device.

14. The package of claim 13 further comprising a lens with the encapsulant mechanically and optically coupling the lens and the light emitting device.

15. The package of claim 14 further comprising an ultraviolet filter situated between the lens and the light emitting device.

16. The package of claim 13 wherein a thickness (t1) of integral material of the reflector cup comprises a substantially similar thickness as a thickness (t2) of the leads.

17. The package of claim 13 wherein a thickness (t3) of integral material of the reflector cup is thicker than a thickness (t2) of the leads.

18. The package of claim 17 wherein at least one of the leads is coupled to a light emitting surface of the integral material of the reflector cup and wraps around the encapsulant to be substantially planar to a non-light emitting surface of the integral material of the reflector cup.

19. A method for fabricating a surface mount light emitting device package comprising:
situating a light emitting device within a thermally and electrically conductive reflector cup of a surface mount lead frame, the lead frame comprising leads;
coupling the light emitting device to the leads; and
disposing encapsulant around the light emitting device and around the reflector cup.

20. The method of claim 19 wherein disposing encapsulant comprises disposing a first encapsulant around the reflector cup and disposing a second encapsulant around the light emitting device.

21. The method of claim 20 wherein disposing the second encapsulant occurs after situating the light emitting device within the reflector cup.

22. The method of claim 20 wherein the first and second encapsulants comprise the same materials.

23. The method of claim 22 wherein the first and second encapsulants are disposed simultaneously.

24. The method of claim 20 wherein the first and second encapsulants comprise different materials.

25. The method of claim 24 wherein the second encapsulant comprises a substantially transparent material.

26. The method of claim 20 wherein the reflector cup comprises an integral reflector cup.

27. The method of claim 26 wherein at least one of the leads is substantially planar to a light emitting surface of the reflector cup, and further comprising, prior to disposing the first encapsulant, wrapping forming the at least one of the leads so as to be substantially planar to a non-light emitting surface of the integral material of the reflector cup.

28. The method of claim 27 wherein a thickness (t1) of integral material of the reflector cup comprises a substantially similar thickness as a thickness (t2) of the leads.

29. The method of claim 27 wherein a thickness (t3) of integral material of the reflector cup is thicker than a thickness (t2) of the leads.

30. The method of claim 19 wherein a thickness (t3) of integral material of the reflector cup is thicker than a thickness (t2) of the leads.

31. The method of claim 19 wherein disposing the encapsulant comprises disposing the encapsulant so as to form a lens with respect to the light emitting device.

32. The method of claim 19 further comprising providing a lens with the encapsulant mechanically and optically coupling the lens and the light emitting device.

33. The method of claim 32 further comprising situating an ultraviolet filter between the lens and the light emitting device.
